(19) United States
(12) Patent Application Publication
(10) Pub. No.: US 2023/0053417 A1
(43) Pub. Date: Feb. 23, 2023

(54) FILM DEPOSITION METHODS IN FURNACE TUBE, AND SEMICONDUCTOR DEVICES

(71) Applicant: CHANGXIN MEMORY TECHNOLOGIES, INC., Hefei City, Anhui (CN)

(72) Inventor: Qizan HUANG, Hefei City, Anhui (CN)

(21) Appl. No.: 17/438,831

(22) PCT Filed: May 24, 2021
(86) PCT No.: PCT/CN2021/095463

§ 371 Date: Sep. 13, 2021

(30) Foreign Application Priority Data
Dec. 3, 2020 (CN) 202011394386.0

(51) Int. Cl. C23C 16/46; C23C 16/34; C23C 16/56; C23C 16/455; C23C 16/52; H01L 21/02

(52) U.S. Cl. CPC C23C 16/46; C23C 16/345; C23C 16/56; C23C 16/45525; C23C 16/52; H01L 21/0217; H01L 21/0228

(57) ABSTRACT

The present disclosure discloses a film deposition method in furnace tube, and a semiconductor device. The film deposition method in furnace tube includes: providing a furnace tube, a process chamber in the furnace tube being divided into a plurality of process regions in the top-bottom direction, a plurality of temperature controllers being in one-to-one correspondence to the plurality of process regions to separately control the temperature of the plurality of process regions; providing a substrate, performing a deposition process of a film on the substrate, the temperature controllers being controlled so that the set deposition temperatures of the process regions gradually decrease in a gradient in the top-to-bottom direction; and performing an annealing process, the temperature controllers being controlled so that the set annealing temperatures of the process regions gradually increase in a gradient in the top-to-bottom direction.

### CROSS-REFERENCE TO RELATED APPLICATIONS

The present disclosure claims the priority to Chinese Patent Application 202011394386.0, titled “Film deposition methods in furnace tube, and semiconductor devices”, filed to China National Intellectual Property Administration on Dec. 3, 2020, which is incorporated herein by reference in its entirety.

### TECHNICAL FIELD

The present disclosure relates to, but is not limited to, a film deposition method in furnace tube and a semiconductor device.

### BACKGROUND

The nitride layer in the dynamic random access memory (DRAM) is mainly used for sidewall isolation, shielding impurity ions, supporting and chemically mechanically polishing the stop layer. Due to the special structure of the furnace tube, a film of the same thickness is deposited. Since the temperature from the top to the bottom of the furnace tube is different, the density of the film is different. In the subsequent etching process, there is great difference in the rate in etching the film of the semiconductor device formed from the top to the bottom of the furnace tube. This difference affects the performance of the film and is not conducive to the stability of the etching process. The production yield is decreased.

### SUMMARY

The following is a summary of the subject matter detailed herein. This summary is not intended to limit the protection scope defined by the claims.

The present disclosure provides a film deposition method in furnace tube, by which the performance of the film deposited in the furnace tube is more consistent and stable, and which is beneficial to improve the product yield of the furnace tube deposition.

The film deposition method in furnace tube according to an embodiment of the present disclosure comprises: providing a furnace tube, a process chamber in the furnace tube being divided into a plurality of process regions in the top-bottom direction, a plurality of temperature controllers being in one-to-one correspondence to the plurality of process regions to separately control the temperature of the plurality of process regions; providing a substrate, performing a deposition process of a film on the substrate, the temperature controllers being controlled so that the set deposition temperatures of the process regions gradually decrease in a gradient in the top-to-bottom direction; and performing an annealing process, the temperature controllers being controlled so that the set annealing temperatures of the process regions gradually increase in a gradient in the top-to-bottom direction.

According to some embodiments of the present disclosure, a semiconductor device is provided, comprising: a substrate and a film arranged on the surface of the substrate, the film being formed according to the film deposition method in furnace tube described above.

According to the film deposition method in furnace tube in an embodiment of the present disclosure, when the deposition process of the film is performed on the substrate in the deposition furnace tube, the temperature controllers are controlled so that the set deposition temperatures of the process regions in the top-to-bottom direction gradually decrease in a gradient, and thus, the thickness of the film formed on the surface of the substrate in the process regions is the same. An annealing process is performed after the deposition process. The temperature controllers are controlled so that the set annealing temperatures of the process regions in the top-to-bottom direction gradually increase in a gradient, and thus, the performance of the film in the process regions is consistent. For example, the ion blocking ability of the film formed on the substrate in different process regions is consistent. Further, the thickness and performance of the film deposited in the process regions may be kept consistent. In this way, the product yield is improved.

After reading and understanding the drawings and detailed description, other aspects may be understood.

### BRIEF DESCRIPTION OF THE DRAWINGS

The accompanying drawings, which are incorporated in and form a part of this specification, illustrate embodiments of the present disclosure and explain, together with the description, the principles of the present disclosure. In these drawings, like reference numerals identify like elements. The drawings to be described below are some, but not all, embodiments of the present disclosure. Other drawings may be obtained by a person of ordinary skill in the art in accordance with those drawings without paying any creative effort.

FIG. 1 is a schematic process flowchart of a film deposition method in furnace tube according to an embodiment of the present disclosure;

FIG. 2 is a schematic structure diagram of a furnace tube for the film deposition method in furnace tube according to an embodiment of the present disclosure;

FIG. 3 is a schematic structure diagram of the substrate in the top process region, after the deposition process of the film and the annealing process, for the film deposition method in furnace tube according to an embodiment of the present disclosure;

FIG. 4 is a schematic structure diagram of the substrate in the bottom process region, after the deposition process of the film and the annealing process, for the film deposition method in furnace tube according to an embodiment of the present disclosure;

FIG. 5 is a graph of the etching rate of the film formed on the substrate under different annealing process conditions in the process regions;

FIG. 6 is a schematic structure diagram of a semiconductor device in an embodiment of forming a film by the film deposition method in furnace tube according to the present disclosure; and

FIG. 7 is a schematic structure diagram of a semiconductor device in another embodiment of forming a film by the film deposition method in furnace tube according to the present disclosure.

### DETAILED DESCRIPTION

To make the purposes, technical solutions and advantages of the embodiments of the present disclosure clearer, the technical solutions in the embodiments of the present disclosure will be described clearly and completely with reference to the drawings in the embodiments of the present disclosure. Apparently, the embodiments to be described are some, but not all, embodiments of the present disclosure. Based on the embodiments of the present disclosure, all other embodiments obtained by a person of ordinary skill in the art without paying any creative effort should be included in the protection scope of the present disclosure. It is to be noted that the embodiments of the present disclosure and features in the embodiments may be combined if not conflict.

Hereinafter, a film deposition method in furnace tube according to the present disclosure will be described with reference to the accompanying drawings by specific implementations.

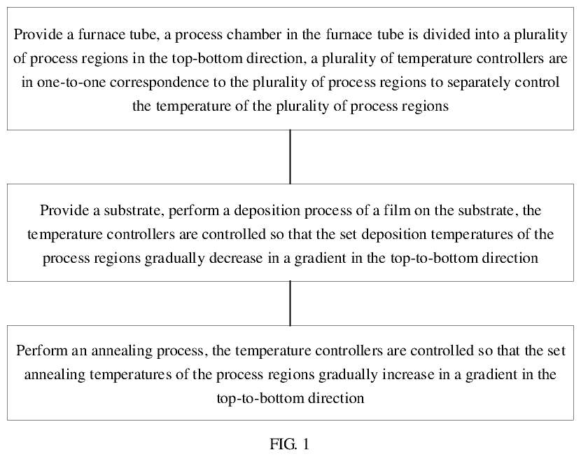

As shown in FIG. 1, the deposition method for a film 2 by using a furnace tube 1000 according to an embodiment of the present disclosure comprises: providing a furnace tube 1000, a process chamber 200 in the furnace tube being divided into a plurality of process regions 201-204 in the top-bottom direction, a plurality of temperature controllers 400 being in one-to-one correspondence to the plurality of process regions 201-204 to separately control the temperature of the plurality of process regions; providing a substrate 1 on which a film 2 is deposited, the temperature controllers 400 being controlled so that the set deposition temperatures of the process regions 201-204 gradually decrease in a gradient in the top-to-bottom direction; and performing an annealing process, the temperature controllers 400 being controlled so that the set annealing temperatures of the process regions gradually increase in a gradient in the top-to-bottom direction.

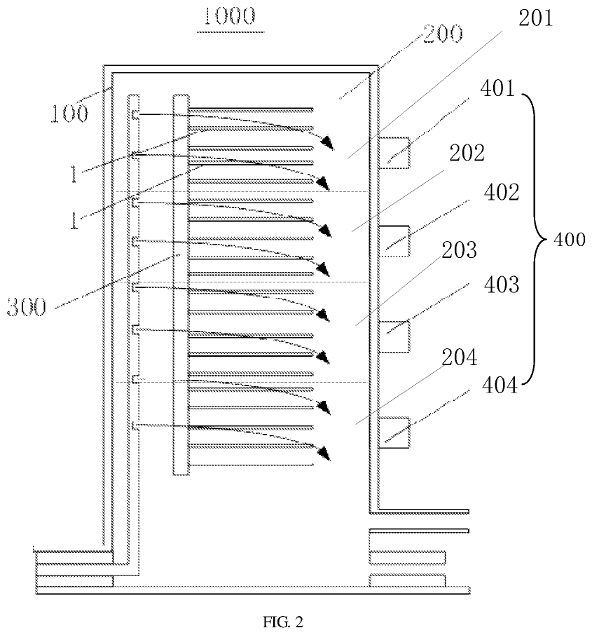

FIG. 2 shows a vertical deposition furnace tube 1000 commonly used in the manufacturing process of semiconductor devices. The deposition furnace tube 1000 may comprise temperature controllers 400, a furnace body 100, a process chamber 200, and a cassette 300. The cassette 300 is used for placing the provided substrate 1. It should be noted that the substrate 1 here may be a die without a device formed or a semiconductor device with a device layer.

The process chamber 200 is formed in the furnace body 100, and may be divided into a plurality of process regions 201-204 in the top-bottom direction. The multiple process regions are in communication with each other. There are multiple temperature controllers 400, and the multiple temperature controllers 400 are in one-to-one correspondence to the multiple process regions. The temperature controllers can control the temperature of multiple process regions to set the temperature of the multiple process regions in different process stages according to process requirements. In FIG. 1, for ease of understanding, multiple process regions are schematically marked in dashed lines. However, this does not mean that, in practical applications, the process chamber 200 is actually divided into multiple process regions, just to show that the multiple temperature controllers 400 can individually control the temperature of the process regions that are in one-to-one correspondence to the temperature controllers. When the deposition process of the film 2 is performed on the substrate 1 in the deposition furnace tube 1000, the temperature controllers 400 are controlled so that the set deposition temperatures of the process regions in the top-to-bottom direction gradually decrease in a gradient. The set deposition temperature of the bottom process region is the lowest, and the set deposition temperature of the top process region is the highest. For example, the process chamber 200 may be divided into four process regions, i.e.: a first process region 201, a second process region 202, a third process region 203, and a fourth process region 204, in the top-to-bottom direction. The temperature controllers 400 comprise a first temperature controller 401, a second temperature controller 402, a third temperature controller 403 and a fourth temperature controller 404. During the deposition process of the film 2, the first temperature controller 401 is set to control the set deposition temperature of the first process region 201 to T1, the second temperature controller 402 is set to control the set deposition temperature of the second process region 202 to T2, the third temperature controller 403 is set to control the set deposition temperature of the third process region 203 to T3, and the fourth temperature controller 404 is set to control the set deposition temperature of the fourth process region 204 to T4, where T4<T3<T2<T1.

During the deposition process, the gas flow rate and gas concentration of the reaction gas passed in the process chamber 200 in the top-bottom direction are different in the process regions, resulting in different thickness of the deposited film 2, further resulting in inconsistent thickness and performance of the film 2 deposited on the substrate 1 on the cassette 300. By controlling the temperature of the process regions, the set deposition temperatures in the top-to-bottom direction gradually decrease in a gradient. The higher the temperature, the higher the deposition rate, the greater the thickness of the film 2; and the lower the temperature, the lower the deposition rate, the smaller the thickness of the film 2. In this way, the deposition rate of the process regions is controlled, so that the thickness of the film 2 deposited on the surface of the substrate 1 in different process regions is the same, so as to improve the product yield.

The annealing process is performed after the deposition process. The temperature controllers 400 are controlled so that the set annealing temperatures of the process regions in the top-to-bottom direction gradually increase in a gradient. The set annealing temperature of the bottom process region is the highest, and the set annealing temperature of the top process region is the lowest. For example, the first temperature controller 401 controls the set annealing temperature of the first process region 201 to T5, the second temperature controller 402 controls the set annealing temperature of the second process region 202 to T6, the third temperature controller 403 controls the set annealing temperature of the third process region 203 to T7, and the fourth temperature controller 404 controls the set annealing temperature of the fourth process region 204 to T8, where T5<T6<T7<T8.

Since the set deposition temperatures of the process regions are different during the deposition process, the deposition reaction under different set deposition temperatures leads to different performance of the deposited film 2. When performing the annealing process, the temperature control is different from that of the deposition process. The process regions, for which the set deposition temperatures are relatively high during the deposition process, have relatively low set annealing temperatures during the annealing process. The process regions, for which the set deposition temperatures are relatively low during the deposition process, have relatively high set annealing temperatures during the annealing process. FIG. 4 is a schematic view of the film 2 deposited on the surface of the substrate 1 in the top process region, and FIG. 5 is a schematic view of the film 2 deposited on the surface of the substrate 1 in the bottom process region. Therefore, referring to FIGS. 4 and 5 together, by controlling the set annealing temperatures of the process regions to gradually increase in the top-to-bottom direction during the annealing process, the film 2 in the process regions is denser and has consistent performance. For example, the ion blocking ability of the film 2 formed on the substrate 1 in different process regions may be consistent. Further, the thickness and performance of the film 2 deposited in the process regions may be kept consistent. In this way, the product yield is improved.

The annealing process lasts for 120 min to 300 min. The flow rate of the gas passed during the annealing process, for example nitrogen, may be 0.1 slm to 0.3 slm. During the annealing process, the film deposition method further comprises: introducing inert gas to the furnace tube 1000, thereby providing a relatively stable annealing environment for the annealing process.

In some embodiments of the present disclosure, the temperature difference between the set deposition temperatures of the process regions is 2° C. to 5° C. That is to say, the temperature difference between the set deposition temperatures of any two adjacent process regions is 2° C. to 5° C. The set deposition temperatures of the process regions are controlled to gradually decrease in a gradient of 2° C. to 5° C. in the top-to-bottom direction. The temperature gradient value may be set according to the size of the process regions and their position in the top-bottom direction.

The set deposition temperatures of the process regions gradually decrease in a constant gradient. That is, the temperature difference between the set deposition temperatures of any two adjacent process regions is the same. The set deposition temperatures of the process regions gradually decrease in a constant gradient (that is a temperature gradient value) in the top-to-bottom direction. For example, if the temperature gradient value of any two adjacent process regions is 2° C., then the set deposition temperatures of the process regions gradually decrease in a gradient of 2° C. The temperature difference between any process region and an adjacent process region is 2° C.

For the set annealing temperature, the temperature difference between the set annealing temperatures of the process regions is 2° C. to 5° C. That is to say, the temperature difference between the set annealing temperatures of any two adjacent process regions is 2° C. to 5° C. The set annealing temperatures of the process regions are controlled to gradually increase in a gradient of 2° C. to 5° C. in the top-to-bottom direction. The temperature gradient value may be set according to the size of the process regions and their position in the top-bottom direction.

The set annealing temperatures of the process regions gradually increase in a constant gradient. That is, the temperature difference between the set annealing temperatures of any two adjacent process regions is the same. The set annealing temperatures of the process regions gradually increase in a constant gradient (that is a temperature gradient value) in the top-to-bottom direction. For example, if the temperature gradient value of any two adjacent process regions is 2° C., then the set annealing temperatures of the process regions gradually increase in a gradient of 2° C. The temperature difference between any process region and an adjacent process region is 2° C.

According to some embodiments of the present disclosure, the set deposition temperatures of the process regions in the top-to-bottom direction during the deposition process are the same as the set annealing temperatures of the process regions in the bottom-to-top direction during the annealing process. As shown in FIG. 2, the process chamber 200 may be divided into four process regions. During the deposition process, the set deposition temperatures of the process regions in the top-to-bottom direction are T1, T2, T3, and T4, respectively. During the annealing process, the set annealing temperatures of the process regions in the top-to-bottom direction are T4, T3, T2, T1, which are opposite to the temperatures during the deposition process. In this way, the thickness and performance of the film 2 formed on the surface of the substrate 1 in different process regions are more consistent. Thus, the etching rate is more consistent during the subsequent etching process.

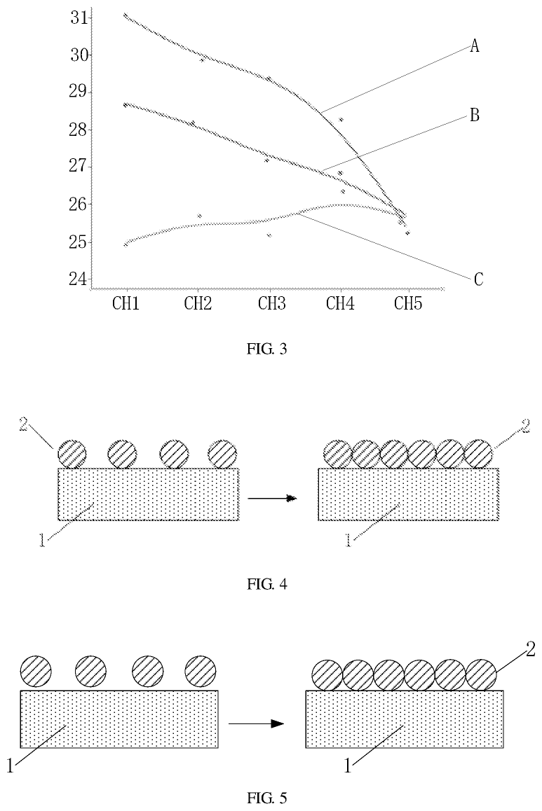

FIG. 3 is a graph of the etching rate of the film 2 under different set deposition temperature and annealing temperature conditions in the process regions. The ordinate is the etching rate, and the abscissa is the process region (Chamber ID). CH1, CH2, CH3, CH4 and CH5 represent the process regions. Line A is a graph of the etching rate of the film 2 in the process regions when no annealing process is performed. Line B is a graph of the etching rate of the film 2 when the set annealing temperatures of the process regions during the annealing process are the same as the set deposition temperatures during the deposition process, that is, a graph of the etching rate of the film 2 in the process regions when the set annealing temperatures of the process regions during the annealing process gradually decrease in a gradient in the top-to-bottom direction. Line C is a graph of the etching rate of the film 2 in the process regions when the set annealing temperatures of the process regions during the annealing process are opposite to the set deposition temperatures during the deposition process. Thus, when the set annealing temperatures of the process regions are controlled to gradually increase in the top-to-bottom direction during the annealing process, the etching rate of the film 2 formed on the surface of the substrate 1 in the process regions is relatively consistent.

The temperature gradient value by which the set deposition temperatures of the process regions gradually decrease in a constant gradient during the deposition process is the same as the temperature gradient value by which the set annealing temperatures of the process regions gradually increase in a constant gradient during the annealing process. In this way, the thickness and performance of the film 2 formed on the substrate 1 obtained in the process regions are more consistent.

The set annealing temperatures of the process regions and the set deposition temperatures of the process regions are greater than or equal to 500° C. and less than or equal to 650° C. In some embodiments, the maximum temperature of the set deposition temperatures during the deposition process of the film 2 and the maximum temperature of the set annealing temperatures during the annealing process are predetermined maximum temperatures. That is, the maximum temperature of the set deposition temperatures during the deposition process of the film 2 and the maximum temperature of the set annealing temperatures during the annealing process may be the same, and may be set a predetermined maximum temperature. The predetermined maximum temperature may be 650° C.

In some embodiments of the present disclosure, the minimum temperature of the set deposition temperatures during the deposition process of the film 2 and the minimum temperature of the set annealing temperatures during the annealing process may be the same. The minimum temperature of the set deposition temperatures during the deposition process of the film 2 and the minimum temperature of the set annealing temperatures during the annealing process may be a predetermined minimum temperature. The predetermined minimum temperature may be 500° C.

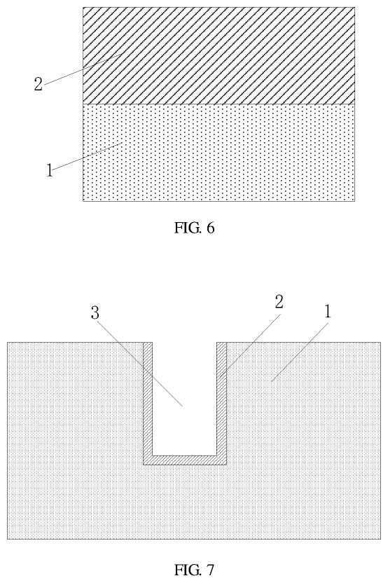

In some embodiments of the present disclosure, the deposition process of the film 2 may comprise, but not limited to, an atomic layer deposition process or a low pressure chemical vapor deposition method. By adjusting the reaction conditions, reaction gas, etc., the deposition process may be applied in other processes of the deposition in the furnace tube 1000. The film 2 formed in the embodiment of the present disclosure may be a silicon nitride film or the like. In some embodiments of the present disclosure, for a device with a thicker deposited film, as shown in FIG. 6, the film 2 is deposited on the surface of the substrate 1, and the surface of the deposited film 2 is a flat and continuous plane. During the deposition process of the film 2, there is a first temperature difference between the set deposition temperatures of any two adjacent process regions; and in the annealing process of the film 2, there is a second temperature difference between the set annealing temperatures of any two adjacent process regions. The first temperature difference may be greater than the second temperature difference. Because the deposited film 2 is relatively thick, the first temperature difference between the set deposition temperatures during the deposition process of the film 2 is relatively large, which is beneficial to the formation of the film 2. The deposition rate of the film 2 and the thickness of the film 2 are increased, so that the formed film 2 has better uniformity. During the annealing process, the temperature difference between the set annealing temperatures of the process regions is controlled to be relatively small, so that the formed film 2 is denser and has better performance. In some embodiments of the present disclosure, for a device with a thinner deposited film, as shown in FIG. 7, a trench 3 is formed on the substrate 1, and the film 2 is formed on the surface of the trench 3 and extends along the surface of the substrate 1. That is, the film 2 covers the surface of the substrate 1 and the inner wall surface of the trench 3, instead of forming a continuous plane. In this case, in the deposition process of the film 2, there is a third temperature difference between the set deposition temperatures of any two adjacent process regions; in the annealing process of the film 2, there is a fourth temperature difference between the set annealing temperatures of any two adjacent process regions; and the third temperature difference is not greater than the fourth temperature difference. That is, the third temperature difference may be less than or equal to the fourth temperature difference. In this case, the formed film 2 is relatively thin. In the deposition process of the film 2, the temperature difference between the set deposition temperatures of any two adjacent process regions is small, so that the difference in the deposition rate of the film 2 is relatively small, which is beneficial to control the thickness and deposition rate of the formed film 2. During the annealing process, the temperature difference between the set annealing temperatures of any two adjacent process regions is greater than or equal to the temperature difference between the set deposition temperatures, so that the formed film 2 is denser and has better performance

Those skilled in the art will readily think of other implementations of the present disclosure by considering the specification and practicing the disclosure disclosed herein. The present disclosure is intended to encompass any variations, uses, or adaptive changes of the present disclosure. These variations, uses, or adaptive changes follow the general principles of the present disclosure and include common knowledge or conventional technical means in the technical field that are not disclosed in the present disclosure. The specification and the embodiments are just exemplary, and the true scope and spirit of the present disclosure are defined by the appended claims.

It should be understood that the present disclosure is not limited to the precise structures that have been described above and shown in the drawings, and various modifications and changes may be made without departing from its scope. The scope of the present disclosure is defined only by the appended claims.

### INDUSTRIAL APPLICABILITY

The present disclosure provides a film deposition method in furnace tube, and a semiconductor device. The film deposition method in furnace tube comprises:

depositing a film on the substrate, and controlling the temperature controllers so that the set deposition temperatures of the process regions gradually decrease in a gradient in the top-to-bottom direction; and performing an annealing process, and controlling the temperature controllers so that the set annealing temperatures of the process regions gradually increase in a gradient in the top-to-bottom direction. In this way, the thickness and performance of the film formed after deposition in the furnace tube are more consistent and stable. Thus, the product yield is improved.

1. A film deposition method in furnace tube, comprising:
providing a furnace tube, a process chamber in the furnace tube being divided into a plurality of process regions in the top-bottom direction, a plurality of temperature controllers being in one-to-one correspondence to the plurality of process regions to separately control the temperature of the plurality of process regions;
providing a substrate, performing a deposition process of a film on the substrate, the temperature controllers being controlled so that the set deposition temperatures of the process regions gradually decrease in a gradient in the top-to-bottom direction; and
performing an annealing process, the temperature controllers being controlled so that the set annealing temperatures of the process regions gradually increase in a gradient in the top-to-bottom direction.

2. The film deposition method in furnace tube according to claim 1, wherein the temperature difference between the set deposition temperatures of any two adjacent process regions is 2° C. to 5° C.

3. The film deposition method in furnace tube according to claim 1, wherein the set deposition temperatures of any two adjacent process regions gradually decrease in a constant gradient.

4. The film deposition method in furnace tube according to claim 1, wherein the temperature difference between the set annealing temperatures of any two adjacent process regions is 2° C. to 5° C.

5. The film deposition method in furnace tube according to claim 1, wherein the set annealing temperatures of any two adjacent process regions gradually increase in a constant gradient.

6. The film deposition method in furnace tube according to claim 3, wherein the set annealing temperatures of any two adjacent process regions gradually increase in a constant gradient.

7. The film deposition method in furnace tube according to claim 6, wherein, the temperature gradient value by which the set deposition temperatures of any two adjacent process regions gradually decrease in a constant gradient is the same as the temperature gradient value by which the set annealing temperatures of any two adjacent process regions gradually increase in a constant gradient.

8. The film deposition method in furnace tube according to claim 6, wherein the set deposition temperatures of the process regions in the top-to-bottom direction during the deposition process of the film are the same as the set annealing temperatures of the process regions in the bottom-to-top direction during the annealing process.

9. The film deposition method in furnace tube according to claim 1, wherein the set annealing temperatures of the process regions and the set deposition temperatures of the process regions are greater than or equal to 500° C. and less than or equal to 650° C.

10. The film deposition method in furnace tube according to claim 1, wherein the maximum temperature of the set deposition temperatures during the deposition process of the film and the maximum temperature of the set annealing temperatures during the annealing process are predetermined maximum temperatures.

11. The film deposition method in furnace tube according to claim 10, wherein the predetermined maximum temperature is 650° C.

12. The film deposition method in furnace tube according to claim 1, wherein the minimum temperature of the set deposition temperatures during the deposition process of the film and the minimum temperature of the set annealing temperatures during the annealing process are predetermined minimum temperatures.

13. The film deposition method in furnace tube according to claim 12, wherein the predetermined minimum temperature is 500° C.

14. The film deposition method in furnace tube according to claim 1, wherein the annealing process lasts for 120 min to 300 min.

15. The film deposition method in furnace tube according to claim 1, during the annealing process, the film deposition method further comprising: introducing inert gas into the furnace tube.

16. The film deposition method in furnace tube according to claim 1, wherein the film is a silicon nitride film.

17. The film deposition method in furnace tube according to claim 1, wherein the deposition process of the film comprises an atomic layer deposition process or a low pressure chemical vapor deposition method.

18. The film deposition method in furnace tube according to claim 6, wherein the film is deposited on the surface of the substrate, the film is a continuous plane; and in the deposition process of the film, there is a first temperature difference between the set deposition temperatures of any two adjacent process regions; in the annealing process of the film, there is a second temperature difference between the set annealing temperatures of any two adjacent process regions; and the first temperature difference is greater than the second temperature difference.

19. The film deposition method in furnace tube according to claim 6, wherein a trench is formed on the substrate, the film is formed on the surface of the trench and extends along the surface of the substrate; and in the deposition process of the film, there is a third temperature difference between the set deposition temperatures of any two adjacent process regions; in the annealing process of the film, there is a fourth temperature difference between the set annealing temperatures of any two adjacent process regions; and the third temperature difference is not greater than the fourth temperature difference.

20. A semiconductor device, comprising: a substrate and a film arranged on the surface of the substrate, the film being formed according to the film deposition method of claim 1.
